(19) United States
(12) Patent Application Publication
(10) Pub. No.: US 2022/0205093 A1
(43) Pub. Date: Jun. 30, 2022

(54) APPARATUS AND METHOD FOR PROCESSING SUBSTRATE

(71) Applicant: SEMES Co., Ltd., Chungcheongnam-do (KR)

(72) Inventors: Hee Hwan Kim, Sejong-si (KR); Cheol Yong Shin, Gyeonggi-do (KR); Jae Youl Kim, Gyeonggi-do (KR); Moon Sik Choi, Seoul (KR)

(21) Appl. No.: 17/526,220

(22) Filed: Nov. 15, 2021

(30) Foreign Application Priority Data
Dec. 29, 2020 (KR) 10-2020-0186120

(51) Int. Cl. C23C 16/458; C23C 16/455

(52) U.S. Cl. CPC C23C 16/4584; C23C 16/45565

(57) ABSTRACT

According to the disclosed substrate processing apparatus, a first bowl is located to correspond to a substrate, and a first chemical solution supply module supplies a first chemical solution while a support module rotates at a first speed, and a second bowl is located to correspond to the substrate, and a second chemical solution supply module supplies a second chemical solution at a first flow rate while a support module rotates at a second speed equal to or smaller than the first speed, and the second bowl is located to correspond to the substrate, and the second chemical solution supply module does not supply the second chemical solution or supplies the second chemical solution at a second flow rate smaller than the first flow rate while the support module rotates at a third speed smaller than the second speed.

### CROSS REFERENCE TO RELATED APPLICATIONS

This application claims the benefit of Korean Patent Application No. 10-2020-0186120, filed on Dec. 29, 2020, in the Korean Intellectual Property Office, the disclosure of which is incorporated herein by reference in its entirety.

### FIELD OF THE INVENTION

The present invention relates to a substrate processing apparatus and method.

### DESCRIPTION OF THE RELATED ART

When manufacturing a semiconductor device or a display device, various processes such as photography, etching, ashing, ion implantation, and thin film deposition are performed. Here, the etching process is a process of removing a layer formed on the substrate, and the cleaning process is a process of removing contaminants remaining on the surface of the substrate. The etching/cleaning process is classified into a wet method and a dry method according to the process progressing method, and the wet method is classified into a batch type method and a spin type method.

In the spin-type method, after fixing the substrate to a support module capable of processing a single substrate, the chemical solution is supplied to the substrate through a nozzle while rotating the substrate, so that the chemical solution is spread over the entire surface of the substrate by centrifugal force.

### SUMMARY OF THE INVENTION

However, since the chemical solution is continuously supplied while rotating the substrate during the etching/cleaning process, an excessive amount of the chemical solution is used compared to the etching amount or the cleaning amount.

An aspect of the present invention is a substrate processing apparatus and method for saving a chemical solution.

The aspects of the present invention are not limited to the aspect mentioned above, and other aspects not mentioned will be clearly understood by those skilled in the art from the following description.

One aspect of the substrate processing apparatus of the present invention for achieving the above comprises a support module, on which a substrate is seated, and rotatable; a housing surrounding the support module and including a first bowl and a second bowl disposed inside the first bowl; a first chemical solution supply module for discharging a first chemical solution to the substrate; and a second chemical solution supply module for discharging a second chemical solution different from the first chemical solution to the substrate, wherein the first bowl is located to correspond to the substrate, and the first chemical solution supply module supplies a first chemical solution while the support module rotates at a first speed, wherein the second bowl is located to correspond to the substrate, and the second chemical solution supply module supplies the second chemical solution at a first flow rate while the support module rotates at a second speed equal to or smaller than the first speed, wherein the second bowl is located to correspond to the substrate, and the second chemical solution supply module does not supply the second chemical solution or supplies the second chemical solution at a second flow rate smaller than the first flow rate while the support module rotates at a third speed smaller than the second speed.

Another aspect of the substrate processing apparatus of the present invention for achieving the above comprises a support module, on which a substrate is seated, and rotatable; a housing surrounding the support module and including a first bowl and a second bowl disposed inside the first bowl; a first chemical solution supply module for discharging a first chemical solution to the substrate; and a second chemical solution supply module for discharging a second chemical solution different from the first chemical solution to the substrate, wherein the first bowl is located to correspond to the substrate, and the first chemical solution supply module supplies a first chemical solution while the support module rotates at a first speed, wherein the support module rotates at a second speed smaller than the first speed while the housing moves so that a second bowl corresponds to the substrate, and the first chemical solution supply module supplies a first chemical solution, wherein the second bowl is located to correspond to the substrate, and the second chemical solution supply module supplies the second chemical solution at a first flow rate while the support module rotates at the second speed, wherein the second bowl is located to correspond to the substrate, and the second chemical solution supply module stops supply of the second chemical solution while the support module rotates at a third speed smaller than the second speed, wherein the support module rotates at a fourth speed greater than the first speed while the housing moves so that a first bowl corresponds to the substrate, and the second chemical solution supply module supplies the second chemical solution at a second flow rate greater than the first flow rate, wherein the first bowl is located to correspond to the substrate, and the first chemical solution supply module supplies the first chemical solution while the support module rotates at the fourth speed.

One aspect of the substrate processing method of the present invention for achieving the above comprises providing a substrate processing apparatus including a support module, on which a substrate is seated, and rotatable, a housing surrounding the support module and including a first bowl and a second bowl disposed inside the first bowl, a first chemical solution supply module for discharging a first chemical solution to the substrate, and a second chemical solution supply module for discharging a second chemical solution different from the first chemical solution to the substrate, locating the first bowl to correspond to the substrate, and supplying the first chemical solution by the first chemical solution supply module while the support module rotates at a first speed, locating the second bowl to correspond to the substrate, and supplying the second chemical solution at a first flow rate by the second chemical solution supply module while the support module rotates at a second speed equal to or smaller than the first speed, and locating the second bowl to correspond to the substrate, and not supplying the second chemical solution or supplying the second chemical solution at a second flow rate smaller than the first flow rate by the second chemical solution supply module while the support module rotates at a third speed smaller than the second speed.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view for describing a substrate processing apparatus according to an embodiment of the present invention;

FIGS. 2(a) and 2(b) are views for describing a method of driving the substrate processing apparatus of FIG. 1;

FIG. 3 is a view for describing an effect of the substrate processing apparatus of FIG. 1;

FIGS. 4 and 5 are cross-sectional views for describing a substrate processing apparatus according to another embodiment of the present invention;

FIG. 6 is a diagram for describing an example of a method of driving the substrate processing apparatus of FIGS. 4 and 5;

FIG. 7 is a diagram for describing another example of a method of driving the substrate processing apparatus of FIGS. 4 and 5;

FIG. 8 is a cross-sectional view for describing a substrate processing apparatus according to another embodiment of the present invention;

FIG. 9 is a view for describing an example of a method of driving the substrate processing apparatus of FIG. 8; and

FIG. 10 is a diagram for describing another example of a method of driving the substrate processing apparatus of FIG. 8.

### DETAILED DESCRIPTION OF THE INVENTION

Hereinafter, preferred embodiments of the present invention will be described in detail with reference to the accompanying drawings. Advantages and features of the present invention, and methods for achieving them will be clarified with reference to embodiments described below in detail together with the accompanying drawings. However, the present invention is not limited to the embodiments disclosed below, but may be implemented in various different forms, and only the embodiments allow the publication of the present invention to be complete, and are provided to fully inform those skilled in the technical field to which the present invention pertains of the scope of the invention, and the invention is only defined by the scope of the claims. The same reference numerals refer to the same elements throughout the specification.

When elements or layers are referred to as “on” or “above” of other elements or layers, it includes not only when directly above of the other elements or layers, but also other elements or layers intervened in the middle. On the other hand, when elements are referred to as “directly on” or “directly above,” it indicates that no other element or layer is intervened therebetween.

The spatially relative terms “below,” “beneath,” “lower,” “above,” “upper,” etc., as shown in figures, can be used to easily describe the correlation of components or elements with other components or elements. The spatially relative terms should be understood as terms including the different direction of the element in use or operation in addition to the direction shown in the figure. For example, if the element shown in the figure is turned over, an element described as “below” or “beneath” the other element may be placed “above” the other element. Accordingly, the exemplary term “below” can include both the directions of below and above. The element can also be oriented in other directions, so that spatially relative terms can be interpreted according to the orientation.

Although the first, second, etc. are used to describe various components, elements and/or sections, these components, elements and/or sections are not limited by these terms. These terms are only used to distinguish one component, element, or section from another component, element or section. Therefore, first component, the first element or first section mentioned below may be a second component, second element, or second section within the technical spirit of the present invention.

The terminology used herein is for describing the embodiments and is not intended to limit the present invention. In the present specification, the singular form also includes the plural form unless otherwise specified in the phrase. As used herein, “comprises” and/or “comprising” means that the elements, steps, operations and/or components mentioned above do not exclude the presence or additions of one or more other elements, steps, operations and/or components.

Unless otherwise defined, all terms (including technical and scientific terms) used in the present description may be used with meanings that can be commonly understood by those of ordinary skill in the art to which the present invention belongs. In addition, terms defined in a commonly used dictionary are not interpreted ideally or excessively unless explicitly defined specifically.

Hereinafter, exemplary embodiments of the present invention will be described in detail with reference to the accompanying drawings, and in the description with reference to the accompanying drawings, the same or corresponding elements are assigned the same reference numbers regardless of reference numerals, and the description overlapped therewith will be omitted.

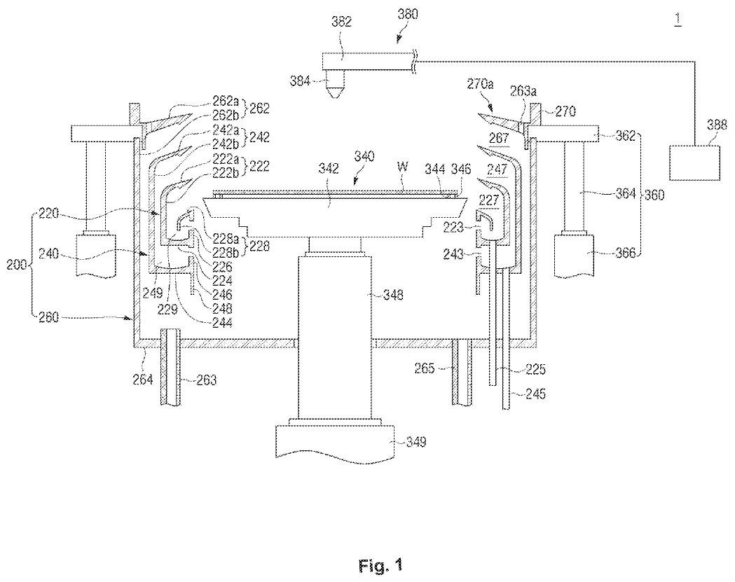

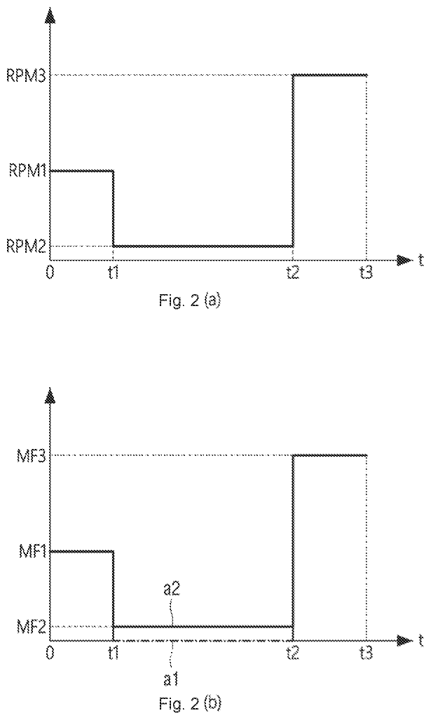

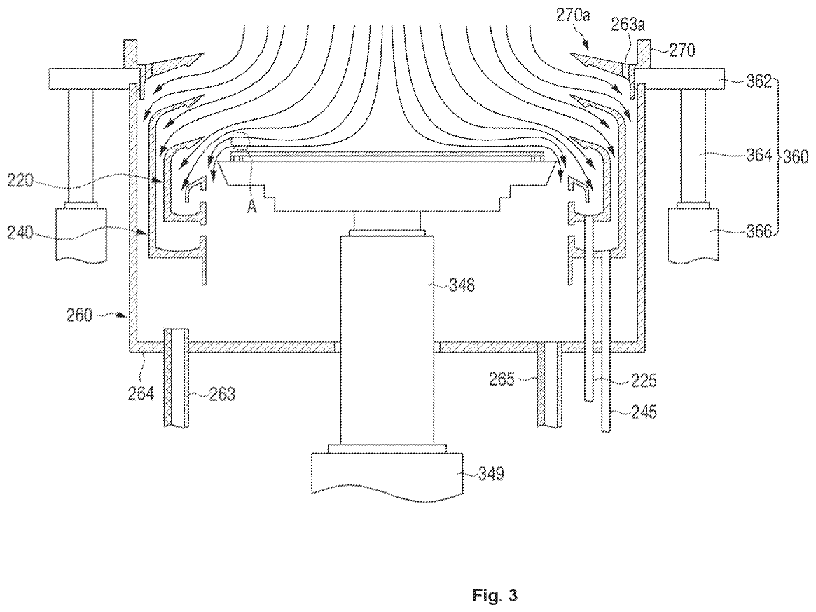

FIG. 1 is a cross-sectional view for describing a substrate processing apparatus according to an embodiment of the present invention. FIG. 2 is a view for describing a method of driving the substrate processing apparatus of FIG. 1. FIG. 3 is a view for describing an effect of the substrate processing apparatus of FIG. 1.

Referring first to FIG. 1, the substrate processing apparatus 1 according to an embodiment of the present invention includes a housing 200, a support module 340, an elevating module 360, and a first chemical solution supply module 380.

The housing 200 provides a processing space, in which a process is performed, and an upper central portion thereof is opened. The housing 200 includes a plurality of bowls 220, 240, 260. According to one example, the housing 200 includes an inner bowl (or a third bowl or a three-stage bowl) 220, an intermediate bowl (or a second bowl or a two-stage bowl) 240, and an outer bowl (or a first bowl or a single-stage bowl) 260. The inner bowl 220, the intermediate bowl 240, and the outer bowl 260 may separate and recover different chemical solutions from among the chemical solutions used in the process. The inner bowl 220 is provided in a hollow cylindrical shape surrounding the support module 340, the intermediate bowl 240 is provided in a hollow cylindrical shape surrounding the inner bowl 220, and the outer bowl 260 is provided in a hollow cylindrical shape surrounding the intermediate bowl 240. That is, the intermediate bowl 240 may be disposed inside the outer bowl 260, and the inner bowl 220 may be disposed inside the intermediate bowl 240. The inner space of the inner bowl 220, the space between the inner bowl 220 and the intermediate bowl 240, and the space between the intermediate bowl 240 and the outer bowl 260 respectively function as an inlet, through which the chemical solution flows into the inner bowl 220, the intermediate bowl 240, and the outer bowl 260. The inner bowl 220, the intermediate bowl 240, and the outer bowl 260 are each connected to the recovery lines 225, 245, 265 extending vertically downward from the bottom surface thereof. Each of the recovery lines 225, 245, 265 discharges the chemical solution introduced through each of the inner bowl 220, the intermediate bowl 240, and the outer bowl 260. The discharged chemical solution may be reused through an external chemical solution regeneration system (not shown).

Next, the shapes of the inner bowl 220, the intermediate bowl 240, and the outer bowl 260 will be described in more detail.

The inner bowl 220 has an outer wall 222, a bottom wall 224, an inner wall 226, and a guide wall 228. Each of the outer wall 222, the bottom wall 224, the inner wall 226, and the guide wall 228 has a ring shape. The outer wall 222 has an inclined wall 222a inclined downwardly in a direction away from the support module 340 and a vertical wall 222b extending vertically downward from a lower end thereof. The bottom wall 224 extends horizontally from the lower end of the vertical wall 222b toward the support module 340. The end of the bottom wall 224 extends to the same position as the upper end of the inclined wall 222a. The inner wall 226 extends vertically upward from the inner end of the bottom wall 224. The inner wall 226 extends to a position such that its upper end is spaced apart from the upper end of the inclined wall 222a by a predetermined distance. The space spaced apart in the vertical direction between the inner wall 226 and the inclined wall 222a functions as the inlet 227 of the inner bowl 220 described above.

A plurality of openings 223 are formed in the inner wall 226 in a ring arrangement. Each of the openings 223 is provided in a slit shape. The opening 223 functions as an exhaust port, through which the gases introduced into the inner bowl 220 are discharged to the outside through the space below the support module 340.

The guide wall 228 has an inclined wall 228a that is inclined downwardly in a direction away from the support module 40 from the upper end of the inner wall 226 and a vertical wall 228b that extends vertically downward from the lower end thereof. The lower end of the vertical wall 228b is located to be spaced apart from the bottom wall 224 by a predetermined distance. The guide wall 228 guides the chemical solution introduced through the inlet 227 to flow smoothly into the space 229 surrounded by the outer wall 222, the bottom wall 224, and the inner wall 226.

The intermediate bowl 240 has an outer wall 242, a bottom wall 244, an inner wall 246, and a protruding wall 248. The outer wall 242, the bottom wall 244, and the inner wall 246 of the intermediate bowl 240 have a shape substantially similar to that of the outer wall 222, the bottom wall 224, and the inner wall 226 of the inner bowl 220. However, the intermediate bowl 240 has a larger size than the inner bowl 220 so as to surround the inner bowl 220. The upper end of the inclined wall 242a of the outer wall 242 of the intermediate bowl 240 and the upper end of the inclined wall 222a of the outer wall 222 of the inner bowl 220 are spaced apart from each other by a predetermined distance in the vertical direction. The spaced space functions as the inlet 247 of the intermediate bowl 240. The protruding wall 248 extends vertically downward from the end of the bottom wall 244. The upper end of the inner wall 246 of the intermediate bowl 240 is in contact with the end of the bottom wall 224 of the inner bowl 220. The slit-shaped exhaust ports 243 for discharging gas are provided on the inner wall 246 of the intermediate bowl 240 in a ring arrangement.

The outer bowl 260 has an outer wall 262, a bottom wall 264, and a protruding wall 270. The outer wall 262 of the outer bowl 260 has a shape similar to that of the outer wall 242 of the intermediate bowl 240, but has a larger size than the intermediate bowl 240 so that the outer bowl 260 surrounds the intermediate bowl 240. The inclined wall 262a of the outer bowl 260 extends from the upper end of the vertical wall 262b to be inclined upwardly along the inward direction. The inclined wall 262a is provided as an upper wall of the housing having an open center. A discharge hole 263a is formed in the inclined wall 262a of the outer bowl 260. The discharge hole 263a is located adjacent to the vertical wall. A plurality of discharge holes 263a are provided. Each discharge hole 263a may be formed along the circumferential direction of the inclined wall 262a. The plurality of discharge holes 263a may be provided in combination with each other to have an annular ring shape. The protruding wall 270 is provided to protrude upwardly from the upper end of the vertical wall 262b. The protruding wall 270 is provided in an annular ring shape having the same diameter as the vertical wall 262b. The protruding wall 270 and the inclined wall 262a are combined with each other to form a liquid storage space 270a. The liquid storage space 270a is provided to communicate with the inner space of the outer bowl 220 through the discharge hole 263a. The upper end of the inclined wall 262a of the outer bowl 260 and the upper end of the inclined wall 242b of the intermediate bowl 240 are located to be spaced apart by a predetermined distance in the vertical direction, and the spaced space functions as the inlet 267 of the outer bowl 260. The bottom wall 264 has a substantially disk shape, and an opening, into which the support shaft (a rotation shaft) 348 is inserted, is formed in the center. The outer bowl 260 functions as an outer wall of the entire housing 200.

The support module 340 supports the substrate W in the processing space of the housing 200 and rotates the substrate W. The support module 340 includes a body 342, a support pin 344, a chuck pin 346, and a support shaft (or rotation shaft) 348. The body 342 has an upper surface that is provided as a substantially circular shape when viewed from above. A support shaft 348 rotatable by a motor 349 is fixedly coupled to the bottom surface of the body 342.

A plurality of support pins 344 are provided. The support pins 344 are disposed to be spaced apart from each other at a predetermined interval on the edge of the upper surface of the body 342 and protrude upwardly from the body 342. The support pins 344 are arranged to have an annular ring shape as a whole by combination with each other. The support pin 344 supports the edge of the rear surface of the substrate W so that the substrate W is spaced apart from the upper surface of the body 342 by a predetermined distance.

A plurality of chuck pins 346 are provided. The chuck pin 346 is disposed farther from the center of the body 342 than the support pin 344. The chuck pin 346 is provided to protrude upwardly from the body 342. The chuck pin 346 supports the side portion of the substrate W so that the substrate W is not laterally separated from the proper position when the support module 340 is rotated. The chuck pin 346 is provided to enable linear movement between the standby position and the support position along the radial direction of the body 342. The standby position is a position farther from the center of the body 342 than the support position. When the substrate W is loaded or unloaded from the support module 340, the chuck pin 346 is located at the standby position, and when a process is performed on the substrate W, the chuck pin 346 is located at the support position. In the support position, the chuck pin 346 is in contact with the side portion of the substrate W.

The elevating module 360 may linearly move the housing 200 in the vertical direction. As the housing 200 moves up and down, the relative height of the housing 200 with respect to the support module 340 is changed.

The elevating module 360 has a bracket 362, a moving shaft 364, and a driving unit 366. The bracket 362 is fixedly installed on the outer wall 262 of the housing 200, and a moving shaft 364, which is moved in the vertical direction by the driving unit 366, is fixedly coupled to the bracket 362. When the substrate W is placed on or lifted from the support module 340, the housing 200 descends so that the support module 340 protrudes above the housing 200. In addition, during the process, the height of the housing 200 is adjusted so that the chemical solution can be introduced into the predetermined bowls 220, 240, 260 according to the type of the chemical solution supplied to the substrate W. Contrary to the above, the elevating module 360 may move the support module 340 in the vertical direction.

The first chemical solution supply module 380 supplies the first chemical solution to the substrate W. The first chemical solution supply module 380 includes a first nozzle 384, a nozzle support 382, and a first chemical solution storage unit 388. The first nozzle 384 may wait at the first standby position and move to the first supply position to discharge the first chemical solution onto the substrate W. Here, the first chemical solution may be an etchant, for example, DHF (Dilute HF). The type of the first chemical solution may vary depending on the target material.

Hereinafter, a method of driving the substrate processing apparatus of FIG. 1 will be described with reference to FIG. 2. FIG. 2(a) is a view for describing the rotation speed of the support module 340 during the substrate processing process, and FIG. 2(b) is a view for describing the flow rate of the first chemical solution discharged by the first chemical solution supply module 380 during the substrate processing process.

Referring to FIG. 2, in a period 0 to t1, the support module 340 rotates at a first speed RPM1 to rotate the substrate W. The first speed RPM1 may be, for example, about 100 to 500 RPM. In addition, while the support module 340 rotates the substrate W, the first chemical solution supply module 380 supplies the first chemical solution (etchant) at the first flow rate MF1. A liquid film is formed on the substrate W by the first chemical solution during the period 0 to t1. For example, the period 0 to t1 may be 10 seconds or less (e.g., about 3 to 10 seconds).

Subsequently, in the period t1 to t2, the support module 340 rotates at the second speed RPM2 by decreasing the rotation speed. The second speed RPM2 may be, for example, 0 to 50 RPM. In particular, while rotating at the second speed RPM2, the first chemical solution may not be supplied (see a1 of FIG. 2(b)). Alternatively, even if the first chemical solution is supplied, the first chemical solution may be supplied at a second flow rate MF2 that is significantly smaller than the first flow rate MF1 (see a2 of FIG. 2(b)). In the period t1 to t2, the liquid film formed during the period 0 to t1 is maintained, and the substrate W is etched by the liquid film. The period t1 to t2 may be longer than the period 0 to t1. For example, the period t1 to t2 may vary depending on the type, shape, location, etc. of the material to be etched, but may be, for example, about 1 minute to 5 minutes.

Here, during the period t1 to t2, the first chemical solution is not supplied or is supplied at a second flow rate MF2 smaller than the first flow rate MF1, and thus the consumption amount of the first chemical solution can be significantly reduced.

Subsequently, in the period t2 to t3, the support module 340 rotates at a third speed RPM3 higher than the first speed RPM1 by increasing the rotation speed. The third speed RPM3 may be about 1000 to 1400 RPM, for example, 1300 RPM. In addition, the first chemical solution may be supplied at a third flow rate MF3 greater than the first flow rate MF1. The period t2 to t3 may be shorter than the period t1 to t2, and may be the same as or longer than the period 0 to t1. The period t2 to t3 may be, for example, 10 to 30 seconds.

Specifically, in the period t1 to t2, the first chemical solution is not supplied or is supplied at a small flow rate MF2, and the rotation speed of the support module 340 is also small. Accordingly, the liquid film formed during the period 0 to t1 may shrink, and the liquid film thickness in some area of the substrate W may be reduced to less than or equal to the reference thickness. As such, when the liquid film dries even in some area of the substrate W, there is a high possibility that a defect is generated in that area. Therefore, in the period t2 to t3 immediately following the period t1 to t2, the first chemical solution is supplied at the third flow rate MF3 while the support module 340 is rapidly rotated at the third speed RPM3, so that it is possible to prevent the substrate W from drying out by rapidly regenerating the liquid film. Since the period t2 to t3 is a relatively short time compared to the period t1 to t2, the amount of the chemical solution consumed in the period t2 to t3 is not large.

In addition, if the thickness of the liquid film does not decrease below the reference thickness in the period t1 to t2, the process of the period t2 to t3 (i.e., the first chemical solution is supplied at the third flow rate MF3 while rotating the support module 340 at the third speed RPM3) may be omitted.

Meanwhile, the period t1 to t2 proceeds in a state, in which the inner bowl (the third bowl) (220 in FIG. 1) is located to correspond to the substrate W. Furthermore, the above-described entire period 0 to t3 may proceed in a state, in which the inner bowl 220 is located to correspond to the substrate W.

In this specification, the “bowl A is located to correspond to the substrate W” means a state, in which an imaginary plane formed by the main surface of the substrate W reaches the inlet of the bowl A. As shown in FIG. 1, when an imaginary plane formed by extending the main surface of the substrate W reaches the inlet 227, it may be understood that the inner bowl 220 is located to correspond to the substrate W. Contrary to the illustration, if an imaginary plane formed by extending the main surface of the substrate W reaches the inlet 267, it may be understood that the outer bowl 260 is located to correspond to the substrate W.

Accordingly, when the outer bowl 260 is located to correspond to the substrate W, the substrate W is disposed close to the open upper central portion of the housing 200. On the other hand, when the inner bowl 220 is located to correspond to the substrate W, the substrate W is disposed far from the open upper central portion of the housing 200.

Here, referring to FIG. 3, when the inner bowl 220 is located at a position corresponding to the substrate W, the opening rate is increased, the ventilation rate is improved, and the amount of exhausted air is increased. This is because air may flow through the inlets 227, 247, and 267 of the plurality of bowls 220, 240, and 260, as shown. Accordingly, the wind speed inside the housing 200 decreases, and the vicinity of the edge (region A) of the substrate W is also in a mild condition. That is, the wind speed in the vicinity of the edge of the substrate W (region A) is relatively low.

On the other hand, if the outer bowl 260 is located at a position corresponding to the substrate W, differently from the illustration, since air mainly flows through the inlet 267 of the outer bowl 260, the wind speed in the vicinity of the edge of the substrate is relatively high.

In the period t1 to t2, the chemical solution is not supplied or is supplied at a small flow rate MF2 and the rotation speed of the support module 340 is also small. If the outer bowl 260 is located to correspond to the substrate W in the period t1 to t2, it is difficult to maintain the thickness of the liquid film formed on the substrate W since the wind speed in the vicinity of the edge of the substrate W is relatively high.

On the other hand, as in one embodiment of the present invention, if the inner bowl 220 is located to correspond to the substrate W in the period t1 to t2, it is easy to maintain the thickness of the liquid film formed on the substrate W since the wind speed in the vicinity of the edge of the substrate W is relatively low. Accordingly, even if the chemical solution is not supplied during the period t1 to t2, the liquid film may be maintained at an appropriate level, and thus the etching rate may be maintained at the target level.

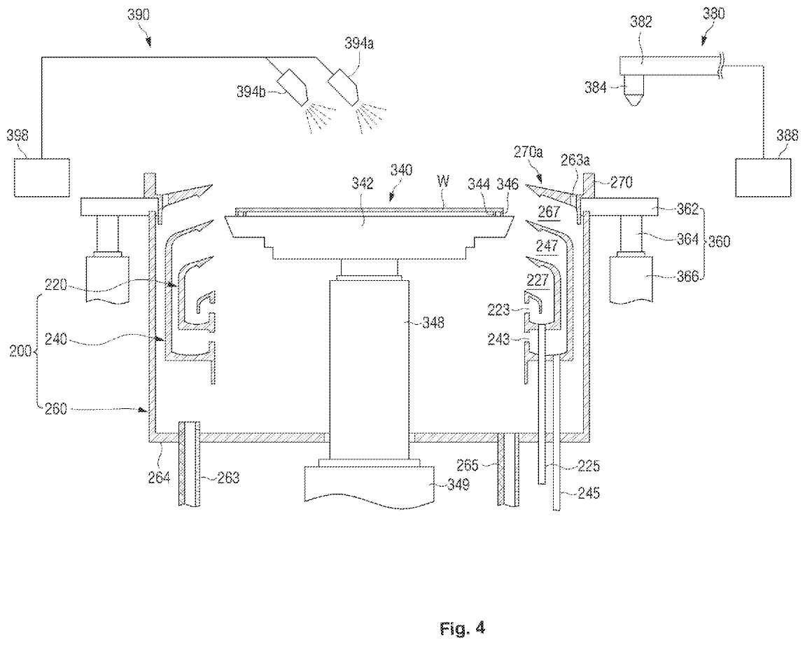

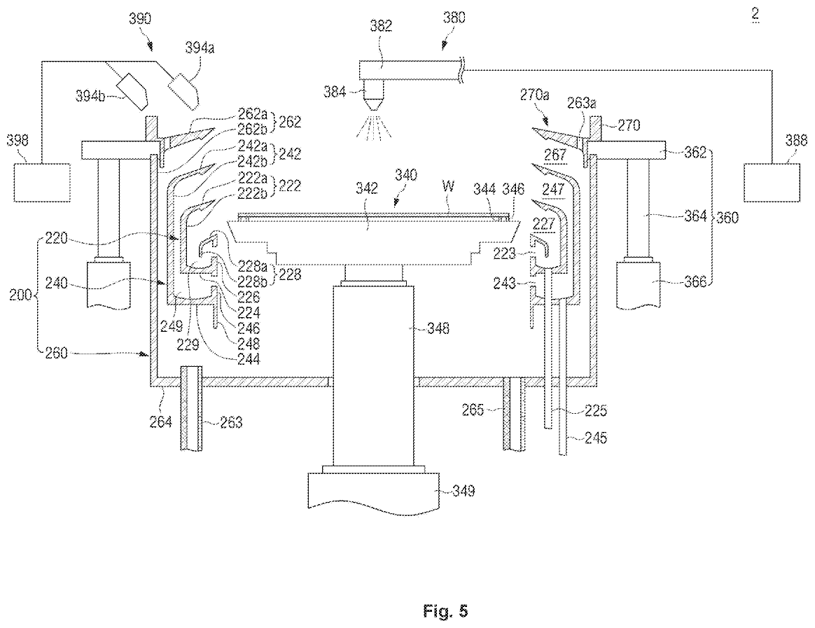

FIGS. 4 and 5 are cross-sectional views for describing a substrate processing apparatus according to another embodiment of the present invention. FIG. 6 is a diagram for describing an example of a method of driving the substrate processing apparatus of FIGS. 4 and 5. Hereinafter, for convenience of description, those substantially the same as those described with reference to FIGS. 1 to 3 will be omitted.

First, referring to FIGS. 4 and 5, a substrate processing apparatus 2 according to another embodiment of the present invention includes a housing 200, a support module 340, an elevating module 360, a first chemical solution supply module 380, and a second chemical solution supply module 390.

The second chemical solution supply module 390 supplies a second chemical solution to the substrate W. The second chemical solution supply module 390 includes second nozzles 394a and 394b, a second chemical solution storage unit 398, and the like. Here, the second chemical solution may be a rinse solution, for example, may be DIW (DeIonized Water). The type of the second chemical solution may vary depending on the target material.

The second nozzles 394a and 394b may be configured in plurality, some nozzles 394a discharge the second chemical solution to the center region of the substrate W, and other nozzles 394b may discharge the second chemical solution to the edge region of the substrate W. The plurality of second nozzles 394a and 394b may simultaneously discharge the second chemical solution, and depending on the design, some nozzles (e.g., 394b) may discharge first and other nozzles (e.g., 394a) may discharge later.

The second nozzles 394a and 394b are a movable type, and may wait at a second standby position and move to a second supply position to discharge the second chemical solution onto the substrate W. Alternatively, unlike the drawings, the second nozzles 394a and 394b are a fixed type, and may be installed at a specific position in the chamber and may not move.

Here, the position (height) of the housing 200 when the first chemical solution supply module 380 discharges the first chemical solution to the substrate W, and the position (height) of the housing 200 when the second chemical solution supply module 390 discharges the second chemical solution to the substrate W may be different from each other.

More specifically, as shown in FIG. 4, the second nozzles 394a and 394b of the second chemical solution supply module 390 move to the second supply position to discharge the second chemical solution. The first nozzle 384 of the first chemical solution supply module 380 waits at the first standby position. Here, when the second chemical solution supply module 390 discharges the second chemical solution to the substrate W, the outer bowl 260 may be located to correspond to the substrate W. That is, an imaginary plane formed by extending the main surface of the substrate W reaches the inlet 267.

As shown in FIG. 5, the first nozzle 384 of the first chemical solution supply module 380 moves to the first supply position to discharge the first chemical solution. The second nozzles 394a and 394b of the second chemical solution supply module 390 move to the second standby position to stand by. Here, when the first chemical solution supply module 380 discharges the first chemical solution to the substrate W, the inner bowl 220 may be located to correspond to the substrate W. That is, an imaginary plane formed by extending the main surface of the substrate W reaches the inlet 227.

Referring to FIG. 6, a pre-cleaning step S10, an etching step S20, and a post-cleaning step S30 are performed in order. The etching step S20 is substantially the same as that described with reference to FIG. 2.

In the period 0 to ta, the support module 340 rotates at the first speed RPM1 to rotate the substrate W. The first speed RPM1 may be, for example, about 100 to 500 RPM. In addition, while the support module 340 rotates the substrate W, the second chemical solution supply module 390 supplies a second chemical solution (rinsing solution). During the period 0 to ta, the substrate W is cleaned by the first chemical solution.

Here, when the second chemical solution supply module 390 discharges the second chemical solution to the substrate W, the outer bowl (i.e., the first bowl) 260 may be located to correspond to the substrate W.

In the period ta to tb, the support module 340 rotates at the first speed RPM1, and the second chemical solution supply module 390 supplies the second chemical solution.

While the second chemical solution supply module 390 supplies the second chemical solution, the elevating module 360 moves the housing 200 in an upward direction. While the second chemical solution supply module 390 supplies the second chemical solution, the first nozzle 384 of the first chemical solution supply module 380 moves from the first standby position to the first supply position. At the end of the period ta to tb (i.e., time tb), the inner bowl (i.e., the third bowl) 220 corresponds to the substrate W, and the first nozzle 384 reaches the first supply position.

In the period tb to t1, the support module 340 rotates at a first speed RPM1 to rotate the substrate W, and the first chemical solution supply module 380 supplies the first chemical solution (etchant) at the first flow rate MF1. A liquid film is formed on the substrate W by the first chemical solution during the period tb to t1.

While the first chemical solution supply module 380 supplies the first chemical solution, the second nozzles 394a and 394b may move from the second supply position to the second standby position.

In the period t1 to t2, the support module 340 rotates at the second speed RPM2 by decreasing the rotation speed. During the time, in which it is rotated at the second speed RPM2, the first chemical solution may not be supplied. Alternatively, even if the first chemical solution is supplied, the first chemical solution may be supplied at a second flow rate MF2 that is significantly smaller than the first flow rate MF1. In the period t1 to t2, the liquid film formed during the period 0 to t1 is maintained, and the substrate W is etched by the liquid film.

In the period t2 to t3, the support module 340 rotates at a third speed RPM3 higher than the first speed RPM1 by increasing the rotation speed. The first chemical solution may be supplied at a third flow rate MF3 greater than the first flow rate MF1.

While the first chemical solution supply module 380 supplies the first chemical solution, the elevating module 360 moves the housing 200 in a downward direction. While the first chemical solution supply module 380 supplies the first chemical solution, the second nozzles 394a and 394b of the second chemical solution supply module 390 move from the second standby position to the second supply position. At the end of the period t2 to t3 (i.e., time t3), the outer bowl (i.e., the first bowl) 260 corresponds to the substrate W, and the second nozzles 394a and 394b reach the second supply position

In the period t3 to t4, the support module 340 rotates at the third speed RPM3 to rotate the substrate W. In addition, while the support module 340 rotates the substrate W, the second chemical solution supply module 390 supplies a second chemical solution (rinse solution). During the period t3 to t4, the substrate W is cleaned by the second chemical solution. Unlike the illustration, the rotation speed of the support module 340 during the period t3 to t4 may be greater than the rotation speed in the period t2 to t3.

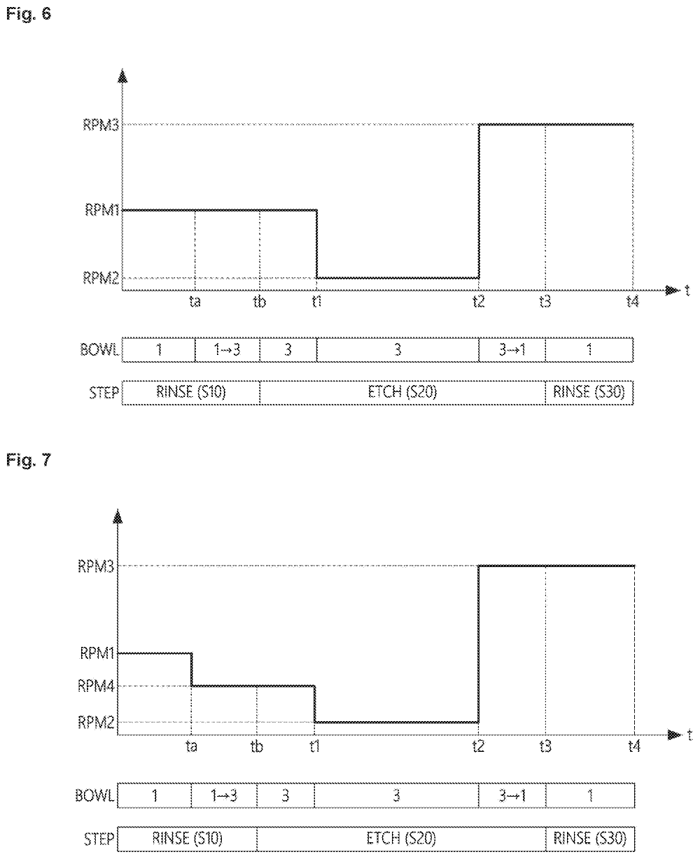

FIG. 7 is a view for describing another example of a method of driving the substrate processing apparatus of FIGS. 4 and 5. Hereinafter, for convenience of description, those substantially the same as those described with reference to FIGS. 4 to 6 will be omitted.

Referring to FIG. 7, a pre-cleaning step (S10), an etching step (S20), and a post-cleaning step (S30) are performed in this order.

In the period ta to tb of the pre-cleaning step (S10), the support module 340 rotates at a fourth speed RPM1 lower than the first speed RPM1 to rotate the substrate W. The fourth speed RPM1 may be about 100 to 300 RPM.

Subsequently, also in the period tb to t1 of the etching step (S20), the support module 340 rotates at the fourth speed RPM1 to rotate the substrate W.

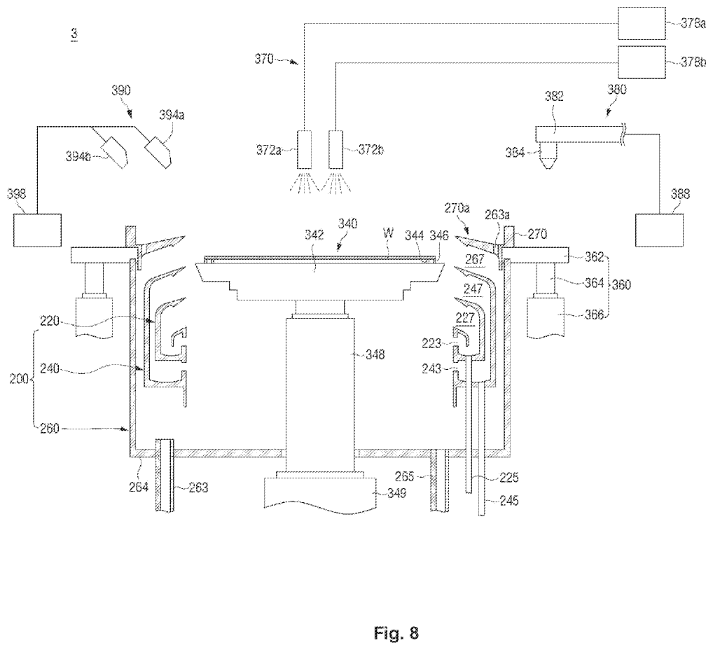

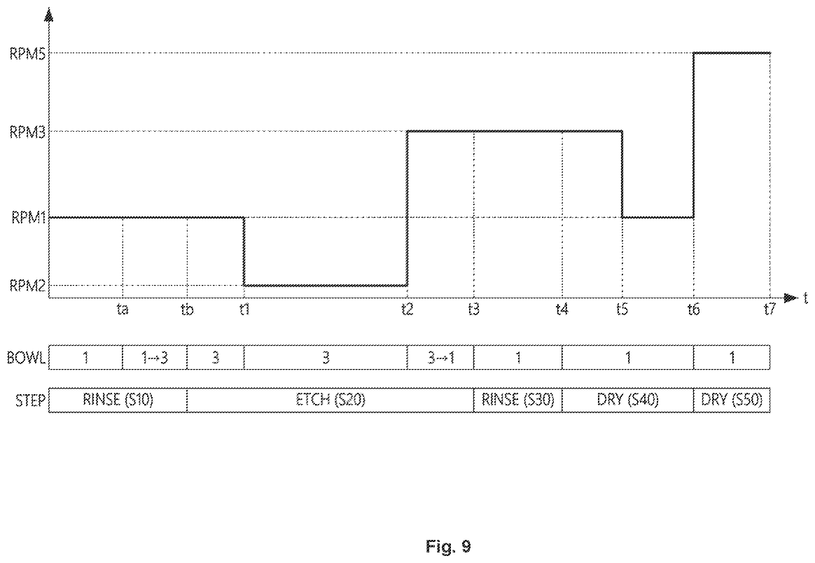

FIG. 8 is a cross-sectional view for describing a substrate processing apparatus according to another embodiment of the present invention. FIG. 9 is a view for describing an example of a method of driving the substrate processing apparatus of FIG. 8. Hereinafter, for convenience of description, those substantially the same as those described with reference to FIGS. 1 to 7 will be omitted.

Referring first to FIG. 8, a substrate processing apparatus 3 according to another embodiment of the present invention includes a housing 200, a support module 340, an elevating module 360, a first chemical solution supply module 380, a second chemical solution supply module 390 and a drying module 370.

The drying module 370 is for drying the substrate W. The drying module 370 includes a third nozzle 372a, a fourth nozzle 372b, a drying solution storage unit 378a, a drying gas storage unit 378b, and the like. Drying solution and drying gas may vary depending on the type of rinse solution. When the rinse solution is DIW, for example, the drying solution may be isopropyl alcohol (IPA), and the drying gas may be nitrogen gas.

Although the drawing shows that the third nozzle 372a and the fourth nozzle 372b are separated from each other, the present invention is not limited thereto. That is, the third nozzle 372a and the fourth nozzle 372b may be formed in one body.

The fourth nozzle 372b may inject the drying gas onto the substrate W in a non-moving state, for example, while not moving in the center region of the substrate W. Alternatively, while the fourth nozzle 372b moves, for example, while moving from the center region of the substrate W to the edge region direction (i.e., scan out), the fourth nozzle 382b may inject the drying gas onto the substrate W.

Alternatively, the third nozzle 372a may inject the drying solution onto the substrate W while moving, and the fourth nozzle 372b may inject the drying gas onto the substrate W while following the third nozzle 372a.

Here, referring to FIG. 9, a pre-cleaning step (S10), an etching step (S20), a post-cleaning step (S30), and drying steps (S40, S50) are performed in this order. In the drying step (S40), drying is performed by a drying solution, and in the drying step (S50), drying is performed by a drying gas.

The etching step (S20) is substantially the same as those described with reference to FIG. 2, and the pre-cleaning step (S10) and the post-cleaning step (S30) are substantially the same as those described with reference to FIG. 6. Accordingly, a description of steps S10, S20, and S30 will be omitted below.

In the period t4 to t5, the support module 340 rotates at the third speed RPM3 to rotate the substrate W. The third speed RPM3 may be, for example, about 1000 to 1400 RPM, and may be, for example, 1300 RPM. Also, while the support module 340 rotates the substrate W, the drying module 370 supplies the drying solution through the third nozzle 372a. That is, in the period t4 to t5, a surface replacement process of replacing the surface of the rinse solution with the drying solution proceeds.

Here, when the drying module 370 discharges the drying solution to the substrate W, the outer bowl (i.e., the first bowl) 260 may be located to correspond to the substrate W.

In the period t5 to t6, the support module 340 rotates at the first speed RPM1 by decreasing the rotation speed, and accordingly the substrate W is rotated. The drying module 370 may continue to supply the drying solution through the third nozzle 372a. Alternatively, supply of the drying solution may be stopped. By rotating at the low rotation speed RPM1, the drying solution and the second chemical solution (i.e., the rinse solution) can be mixed well. That is, in the period t5 to t6, a stirring process for dispersing the rinse solution in the drying solution is performed.

In the period t6 to t7, the support module 340 rotates at the fifth speed RPM5 by increasing the rotation speed, and accordingly, the substrate W is rotated. The drying module 370 supplies drying gas through the fourth nozzle 372b. By supplying drying gas, the stirred liquid can be removed during the period t5 to t6.

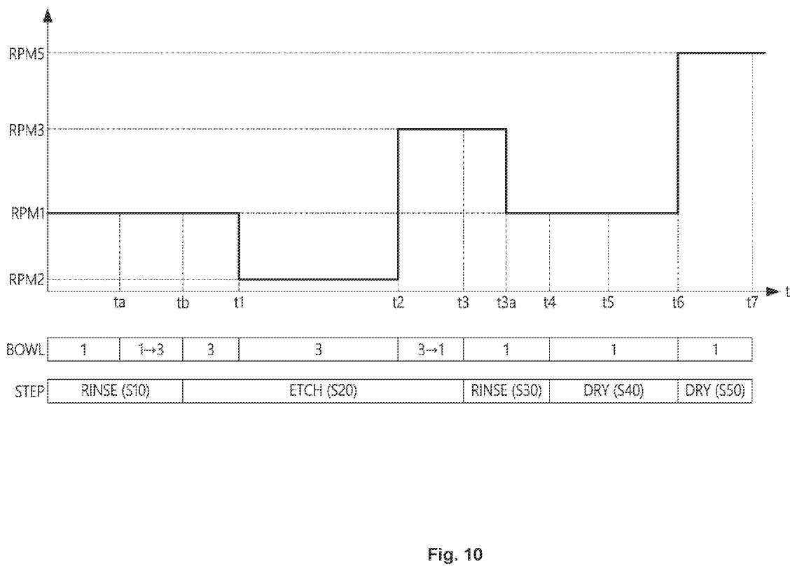

FIG. 10 is a diagram for describing another example of a method of driving the substrate processing apparatus of FIG. 8. Hereinafter, for convenience of description, those substantially the same as those described with reference to FIGS. 8 and 9 will be omitted.

Referring to FIG. 10, a pre-cleaning step (S10), an etching step (S20), a post-cleaning step (S30), and drying steps (S40, S50) are performed in this order.

In the period t3 to t3a of the post cleaning step S30, the support module 340 rotates at the third speed RPM3 to rotate the substrate W. In addition, while the support module 340 rotates the substrate W, the second chemical solution supply module 390 supplies a second chemical solution (rinse solution).

Subsequently, in the period t3a to t4, the support module 340 rotates at the first speed RPM1 by decreasing the rotation speed, and accordingly, the substrate W is rotated. In addition, while the support module 340 rotates the substrate W, the second chemical solution supply module 390 continues to supply the second chemical solution (rinse solution).

Subsequently, in the period t4 to t6, the support module 340 rotates at the third speed RPM3 to rotate the substrate W. Also, while the support module 340 rotates the substrate W, the drying module 370 supplies the drying solution through the third nozzle 372a.

Subsequently, in the period t6 to t7, the support module 340 rotates at the fifth speed RPM5 by increasing the rotation speed, and accordingly, the substrate W is rotated. The drying module 370 supplies drying gas through the fourth nozzle 372b.

Although embodiments of the present invention have been described with reference to the above and the accompanying drawings, those of ordinary skill in the art to which the present invention pertains can understand that the present invention can be practiced in other specific forms without changing its technical spirit or essential features. Therefore, it should be understood that the embodiments described above are illustrative in all respects and not limiting.

What is claimed is:

1. An apparatus for processing a substrate comprising:
a support module, on which a substrate is seated, and rotatable;
a housing surrounding the support module and including a first bowl and a second bowl disposed inside the first bowl;
a first chemical solution supply module for discharging a first chemical solution to the substrate; and
a second chemical solution supply module for discharging a second chemical solution different from the first chemical solution to the substrate,
wherein the first bowl is located to correspond to the substrate, and the first chemical solution supply module supplies a first chemical solution while the support module rotates at a first speed,
wherein the second bowl is located to correspond to the substrate, and the second chemical solution supply module supplies the second chemical solution at a first flow rate while the support module rotates at a second speed equal to or smaller than the first speed,
wherein the second bowl is located to correspond to the substrate, and the second chemical solution supply module does not supply the second chemical solution or supplies the second chemical solution at a second flow rate smaller than the first flow rate while the support module rotates at a third speed smaller than the second speed.

2. The apparatus of claim 1, wherein, after the second chemical solution supply module does not supply the second chemical solution or supplies the second chemical solution at a second flow rate, the second chemical solution supply module supplies the second chemical solution at a third flow rate while the support module rotates at a fourth speed greater than the second speed.

3. The apparatus of claim 2, wherein the third flow rate is greater than the first flow rate.

4. The apparatus of claim 2, wherein the housing moves the first bowl to a position corresponding to the substrate while the second chemical solution supply module supplies a second chemical solution at the third flow rate.

5. The apparatus of claim 4, wherein, after the second chemical solution supply module supplies a second chemical solution at the third flow rate, the first chemical solution supply module supplies a first chemical solution while the support module rotates at the fourth speed in a state where the first bowl is located to correspond to the substrate.

6. The apparatus of claim 1, wherein supplying the second chemical solution at a first flow rate by the second chemical solution supply module proceeds during a first time, and not supplying the second chemical solution or supplying the second chemical solution at a second flow rate by the second chemical solution supply module proceeds during a second time longer than the first time.

7. The apparatus of claim 6, wherein, after the second chemical solution supply module does not supply the second chemical solution or supplies the second chemical solution at a second flow rate, during a third time longer than the first time and shorter than the second time, the second chemical solution supply module supplies the second chemical solution at a third flow rate while the support module rotates at a fourth speed greater than the second speed.

8. The apparatus of claim 1, wherein, after the second chemical solution supply module does not supply the second chemical solution or supplies the second chemical solution at a second flow rate in a state where the first bowl is located to correspond to the substrate, the first chemical solution supply module supplies the first chemical solution while the support module rotates at a fourth speed greater than the second speed.

9. The apparatus of claim 8, wherein a drying module supplies a drying solution onto the substrate while the support module rotates at a fifth speed smaller than the fourth speed in a state where the first bowl is located to correspond to the substrate, and then the drying module supplies a drying gas onto the substrate while the support module rotates at a sixth speed greater than the fourth speed.

10. The apparatus of claim 1, wherein, between supplying the first chemical solution by the first chemical solution supply module and supplying a second chemical solution at a first flow rate by the second chemical solution supply module, the housing moves the second bowl to a position corresponding to the substrate while the first chemical solution supply module supplies a first chemical solution.

11. The apparatus of claim 1, wherein a wind speed in the vicinity of an edge of the substrate is a first wind speed when the first bowl is located to correspond to the substrate, a wind speed in the vicinity of an edge of the substrate is a second wind speed when the second bowl is located to correspond to the substrate, and the second wind speed is smaller than the first wind speed.

12. The apparatus of claim 1, wherein the first chemical solution is a rinse solution, and the second chemical solution is an etchant.

13. An apparatus for processing a substrate comprising:
a support module, on which a substrate is seated, and rotatable;
a housing surrounding the support module and including a first bowl and a second bowl disposed inside the first bowl;
a first chemical solution supply module for discharging a first chemical solution to the substrate; and
a second chemical solution supply module for discharging a second chemical solution different from the first chemical solution to the substrate,
wherein the first bowl is located to correspond to the substrate, and the first chemical solution supply module supplies a first chemical solution while the support module rotates at a first speed,
wherein the support module rotates at a second speed smaller than the first speed while the housing moves so that a second bowl corresponds to the substrate, and the first chemical solution supply module supplies a first chemical solution,
wherein the second bowl is located to correspond to the substrate, and the second chemical solution supply module supplies the second chemical solution at a first flow rate while the support module rotates at the second speed,
wherein the second bowl is located to correspond to the substrate, and the second chemical solution supply module stops supply of the second chemical solution while the support module rotates at a third speed smaller than the second speed,
wherein the support module rotates at a fourth speed greater than the first speed while the housing moves so that a first bowl corresponds to the substrate, and the second chemical solution supply module supplies the second chemical solution at a second flow rate greater than the first flow rate,
wherein the first bowl is located to correspond to the substrate, and the first chemical solution supply module supplies the first chemical solution while the support module rotates at the fourth speed.

14. The apparatus of claim 13, wherein supplying the second chemical solution at a first flow rate by the second chemical solution supply module proceeds during a first time, stopping supply of the second chemical solution by the second chemical solution supply module proceeds during a second time longer than the first time, and supplying the second chemical solution at a second flow rate by the second chemical solution supply module proceeds during a third time longer than the first time and shorter than the second time.

15. The apparatus of claim 13, wherein, after the first chemical solution supply module supplies the first chemical solution while the support module rotates at the fourth speed, the first bowl is located to correspond to the substrate, and a drying module supplies a drying solution onto the substrate while the support module rotates at a fifth speed smaller than the fourth speed, and then the drying module supplies a drying gas onto the substrate while the support module rotates at a sixth speed greater than the fourth speed.

16. A method for processing a substrate comprising:
providing a substrate processing apparatus including a support module, on which a substrate is seated, and rotatable, a housing surrounding the support module and including a first bowl and a second bowl disposed inside the first bowl, a first chemical solution supply module for discharging a first chemical solution to the substrate, and a second chemical solution supply module for discharging a second chemical solution different from the first chemical solution to the substrate;
locating the first bowl to correspond to the substrate, and supplying the first chemical solution by the first chemical solution supply module while the support module rotates at a first speed;
locating the second bowl to correspond to the substrate, and supplying the second chemical solution at a first flow rate by the second chemical solution supply module while the support module rotates at a second speed equal to or smaller than the first speed; and
locating the second bowl to correspond to the substrate, and not supplying the second chemical solution or supplying the second chemical solution at a second flow rate smaller than the first flow rate by the second chemical solution supply module while the support module rotates at a third speed smaller than the second speed.

17. The method of claim 16 further comprises,
after the second chemical solution supply module does not supply the second chemical solution or supplies the second chemical solution at a second flow rate, supplying the second chemical solution at a third flow rate greater than the first flow rate by the second chemical solution supply module while the support module rotates at a fourth speed greater than the second speed.

18. The method of claim 17 further comprises,
moving the first bowl to a position corresponding to the substrate by the housing while the second chemical solution supply module supplies a second chemical solution at the third flow rate.

19. The method of claim 18 further comprises,
after the second chemical solution supply module supplies a second chemical solution at the third flow rate, supplying a first chemical solution by the first chemical solution supply module while the support module rotates at the fourth speed in a state where the first bowl is located to correspond to the substrate.

20. The method of claim 16 further comprises,
after the second chemical solution supply module does not supply the second chemical solution or supplies the second chemical solution at a second flow rate in a state where the first bowl is located to correspond to the substrate, supplying the first chemical solution by the first chemical solution supply module while the support module rotates at a fourth speed greater than the second speed.
